(19) United States
(12) Patent Application Publication
(10) Pub. No.: US 2006/0105594 A1
(43) Pub. Date: May 18, 2006

(54) Method for package burn-in testing

(75) Inventor: Wen-Kun Yang, Hsinchu (TW)

Correspondence Address: Gary M. Nath;NATH & ASSOCIATES PLLC, 112 South West Street, Alexandria, VA, 22314, US

(73) Assignee: Advanced Chip Engineering Technology Inc.

(21) Appl. No.: 11/318,552

(22) Filed: Dec. 28, 2005

Related U.S. Application Data
(63) Continuation-in-part of application No. 10/840,421, filed on May 7, 2004.

(30) Foreign Application Priority Data
Feb. 16, 2004 (TW) 93103677

(51) Int. Cl. H05K 1/00

(52) U.S. Cl. 439/68

(57) ABSTRACT

The present invention discloses a contact method of burn-in and test after packaging. The method comprises providing a print circuit board. A solder join socket is engaged with a first fixed plate, the solder join socket with contact spring located in the solder join socket. An adhesive material is formed onto pads area of the print circuit board. The solder join socket is attached to the adhesive material. A second fixed plate is engaged with the first fixed plate and the solder join socket. A third fixed plate is inserted into the solder join socket following up the second fixed plate. A contact ball of a ball grid array (BGA) package is coupled with the contact spring for performing testing. Between the contact ball and the contact spring may keep an approximately constant pressure by utilizing the surface of the third fixed plate contacting with the surface of the ball grid array (BGA) package.

This application is continuation in part application of U.S. patent application Ser. No. 10/840,421, filed on May 07 2004.

### BACKGROUND OF THE INVENTION

1. Field of the Invention

This invention relates to a method of burn-in testing after packaging, and more particularly to a new method by using contact pressure of conductive micro springs, can apply to a conventional package or wafer level package to improve burn-in procedure.

2. Description of the Prior Art

The semiconductor technologies are developing very fast, and especially semiconductor dies have a tendency toward miniaturization. However, the requirements for the functions of the semiconductor dies have an opposite tendency to variety. Namely, the semiconductor dies must have more I/O pads into a smaller area, so the density of the pins is raised quickly. It causes the packaging for the semiconductor dies to become more difficult and decrease the yield.

The main purpose of the package structure is to protect the dies from outside damages. Furthermore, the heat generated by the dies must be diffused efficiently through the package structure to ensure the operation the dies.

The earlier lead frame package technology is already not suitable for the advanced semiconductor dies due to the density of the terminals thereof is too high. Hence, a new package technology of BGA (Ball Grid Array) has been developed to satisfy the packaging requirement for the advanced semiconductor dies. The BGA package has an advantage of that the spherical terminals has a shorter pitch than that of the lead frame package, and the terminals of the BGA are unlikely to be damage and deform. In addition, the shorter signal transmitting distance benefits to raise the operating frequency to conform to the requirement of faster efficiency. Most of the package technologies divide dice on a wafer into respective dies and then to package and test the die respectively. Another package technology, called “Wafer Level Package (WLP)”, can package the dies on a wafer before dividing the dice into respective individual die. The WLP technology has some advantages, such as a shorter producing cycle time, lower cost, and no need to under-fill or molding.

Moreover, the packaged IC continues a series of testing in a conventional package or wafer level package. The contact method of burn-in and test socket in present marketing comprises three type as follows, (1) Pogo Pin: high price and cost of burn-in testing, (2) Metal probe: common reliability, high price and assembly complicated, (3) Membrane contact: high price and low reliability.

In view of the aforementioned drawbacks, a new type contact structure and method of burn-in and test provided by the present invention can improve the above drawbacks. That is to say, the present invention has the advantages as follows: high reliability, low cost, easy assembly and easy to repair. Besides, the present invention can apply to a conventional package and wafer level package etc.

### SUMMARY OF THE INVENTION

The objective of the present invention is to provide a contact method of burn-in and test of the new type wafer level package after packaging.

The present invention discloses a contact method of burn-in and test after packaging. The method comprises providing a print circuit board. A solder join socket is engaged with a first fixed plate, the solder join socket with contact spring located in the solder join socket. An adhesive material is formed onto pads area of the print circuit board. The solder join socket is attached to the adhesive material. A second fixed plate is engaged with the first fixed plate and the solder join socket. A third fixed plate is inserted into the solder join socket following up the second fixed plate. A contact ball of a ball grid array (BGA) package is coupled with the contact spring for performing testing. Between the contact ball and the contact spring may keep an approximately constant pressure by utilizing the surface of the third fixed plate contacting with the surface of the ball grid array (BGA) package.

The method further comprises performing a step of re-flowing process for electrically coupling the solder join socket with the pad after attaching the solder join socket to the adhesive material.

The method further comprises performing a step of pushing the first fixed plate down to the top site of the print circuit board after re-flowing process.

The method further comprises performing a step of coupling a contact ball of a package with the contact spring for performing testing after engaging a third fixed plate with the second fixed plate and the solder join socket.

The bore diameter of the first, second and third fixed plate are the smallest, middle and the highest respectively.

### BRIEF DESCRIPTION OF THE DRAWINGS

The above objects, and other features and advantages of the present invention will become more apparent after reading the following detailed description when taken in conjunction with the drawings, in which:

FIG. 1 is a schematic diagram of engaging solder join socket with a first fixed plate and forming an adhesive material onto a pad area of the print circuit board of the present invention.

FIG. 2 is a schematic diagram of attaching the solder join socket the adhesive material of the present invention.

FIG. 3 is a schematic diagram of performing an IR-reflow process to form a solder paste join on two side of the bottom of the solder join socket of the present invention.

FIG. 4 is a schematic diagram of pushing the first fixed plate down to the top site of the print circuit board of the present invention.

FIG. 5 is a schematic diagram of engaging a second fixed plate with the first fixed plate and the solder join socket of the present invention.

FIG. 6 is a schematic diagram of engaging a third fixed plate with the second fixed plate and the solder join socket of the present invention.

FIG. 7 is a schematic diagram of electrically coupling a contact ball of a package with the contact spring for performing testing of the present invention.

### DESCRIPTION OF THE PREFERRED EMBODIMENT

The present invention discloses a structure and method of burn-in and test for the new type package. It can apply to a testing of a conventional type or wafer level package. Some sample embodiments of the invention will now be described in greater detail. Nevertheless, it should be recognized that the present invention can be practiced in a wide range of other embodiments besides those explicitly described, and the scope of the present invention is expressly not limited expect as specified in the accompanying claims.

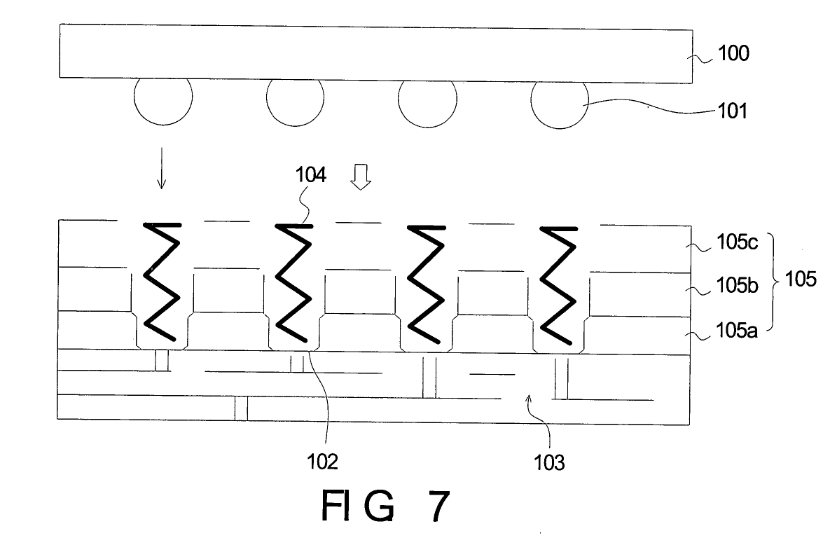

As shown in FIG. 7, it is a schematic diagram of a contact structure of burn-in and test for package. The ball grid array (BGA) package 100 will now be described but it is not used to limit the present invention. The package 100 has a plurality of contact metal balls 101. The contact metal balls 101 may be formed by conductive material, such as solder balls.

Solder join socket 102 is fixed on a print circuit board (PCB) 103. In one embodiment, the solder join socket 102 is fixed on the print circuit board 103 by SMT (surface mounting technology) technique. The print circuit board 103 is heat-resistant material, such as FR4, FR5 or BT etc. One feature of the solder join socket 102 comprises that width of upper portion of the opening is wider than that of lower portion of the opening in tangent plane of the solder join socket 102. Therefore, the fixed plate 105 is constructed by a plurality of plates, including upper plate 105c, middle plate 105b and lower plate 105a, wherein bore diameter of the lower plate 105a is minimum one, and bore diameter of the upper plate 105c is maximum one. Of course, a whole shaping fixed plate 105 may be used.

Contact micro metal springs 104 are located on the solder join socket 102. The micro metal springs 104 are fixed on the outlet of the solder join socket 102. The micro metal springs 104 may be contacted with the solder balls 101. The material of the micro metal springs 104 include conductive material, such as metal, alloy etc., preferable stainless steel. The micro metal springs 104 can be removed from the outlet of the solder join socket 102 by some tools. A substantially constant pressure is created between the solder balls and the metal springs. The ball may self-align into the hole of the plates. The pressure of the solder balls keeps independent. The micro metal springs 104 are located on the print circuit board to electrically couple with conductive circuit.

Surfaces of the fixed plate 105 and the micro metal springs 104 are approximately or substantially at same level, and material of the fixed plate 105 and the print circuit board 103 is the same or similar, such as FR4, FR5 or BT etc. Besides, the fixed plate 105 is located among the solder join socket 102. The solder balls 101 continue downward pressing after contacting with the micro metal springs 104, and depth of pressing such as is 380 micron. Because the fixed plate 105 and the micro metal springs 104 are approximately at same level, the depth of pressing of the solder balls 101 can not exceed diameter of the solder balls 101. Therefore, an approximately constant and self-aligned pressure is kept between the solder balls 101 and the micro metal springs 104 by using the surface of the fixed plate 105 contacting with the surface of the ball grid array (BGA) package 100.

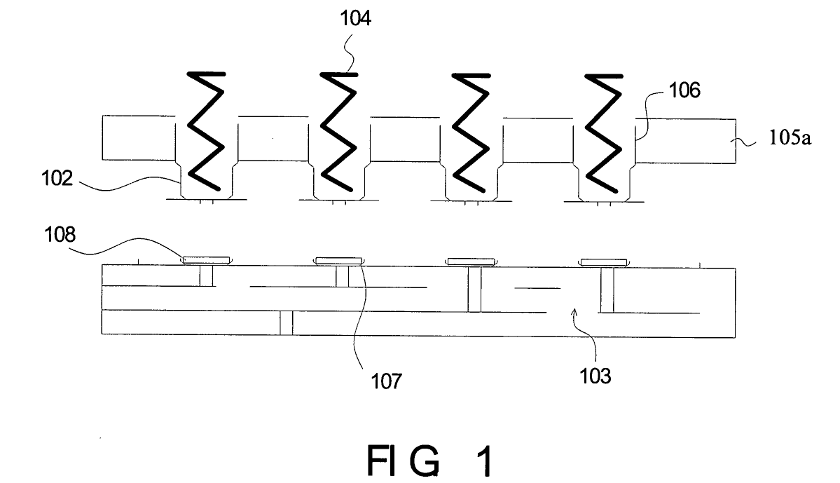

The contact method of burn-in and test of new type wafer level package disclosed of the present invention comprises the following steps shown in FIG. 1: firstly, providing a print circuit board 103. Next, a solder join socket 102 is engaged with a first fixed plate 105a by utilizing inserting the solder join socket 102 into the hole of the first fixed plate 105a from the bottom to the outlet 106 of the solder join socket 102. The metal springs 104 are located in the solder join socket 102. And then, an adhesive material 108 is formed onto a pad area 107 of the print circuit board 103 utilizing the SMT (surface mounting technology) process to print a solder paste onto the pad area 107 of the print circuit board 103.

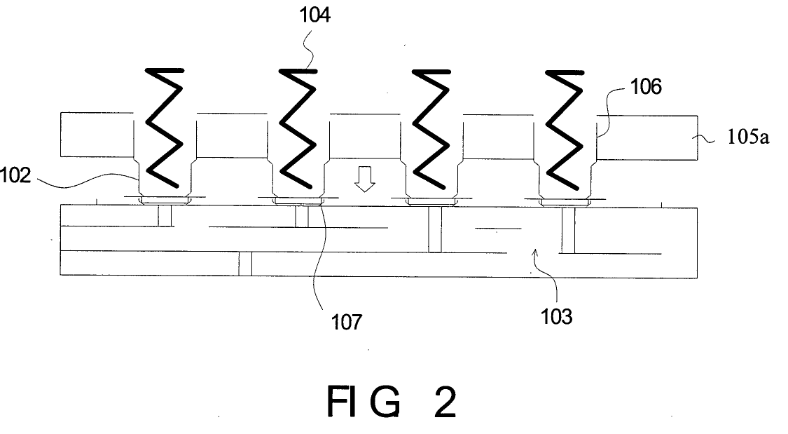

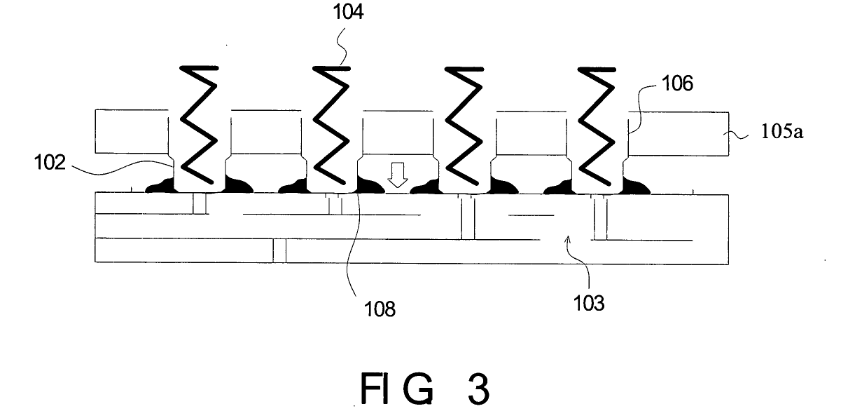

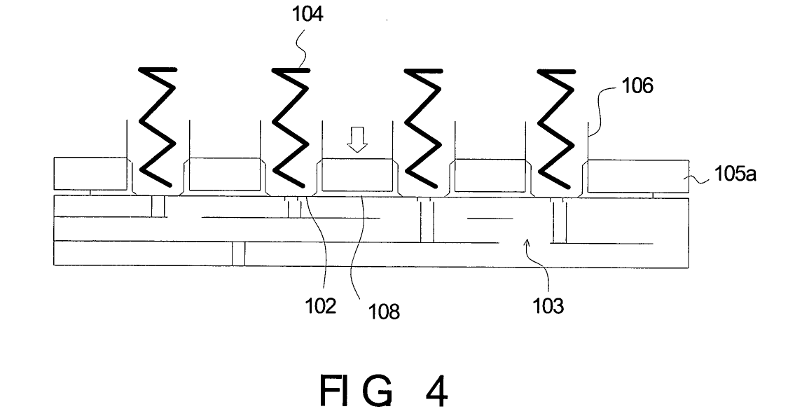

Shown in FIG. 2, the solder join socket 102 is attached to the adhesive material by aligning the solder join socket 102 with the pad area 107. Subsequently, a step of re-flowing process, such as IR-reflow process, is performed to form a solder paste join 108 on two side of the bottom of the solder join socket 102 for electrically coupling the solder join socket 102 with the pad such that the metal springs 104 may be electrically coupled with the pad, shown in FIG. 3. Next, a step of pushing the first fixed plate 105a down to the top site of the print circuit board 13 is performed, shown in FIG. 4, and therefore the first fixed plate 105a are mounted onto the solder paste join 108.

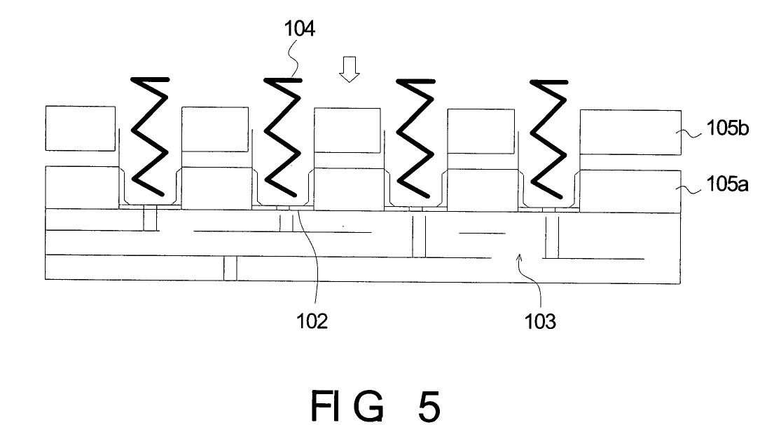

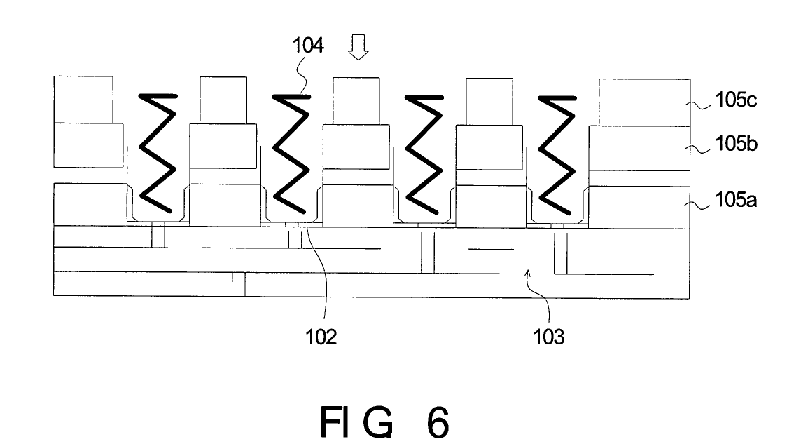

Shown in FIG. 5, a second fixed plate 105b is engaged with the first fixed plate 105a and the solder join socket 102 by utilizing inserting the second fixed plate 105b into the solder join socket 102. The fixed plate and the second fixed plate 105a, 105b have its own holes size, wherein the hole size of the second fixed plate 105b is larger than the first fixed plate 105a. Next, a third fixed plate 105c is engaged with the second fixed plate 105b and the solder join socket 102 by utilizing inserting the third fixed plate 105c into the solder join socket 102 following up the second fixed plate 105b, shown in FIG. 6. The hole size of the third fixed plate 105c is larger than the second fixed plate 105b. Finally, a contact ball, such as solder ball, 101 of a package 100 is electrically coupled with the contact spring 104 for performing testing, shown in FIG. 7. The BGA package 100 can be inserted into the socket 102 once the balls 101 drop into the hole, and it can hold once pushing the back-site of the BGA package 100.

Between the solder balls 101 and the contact springs 104 keeps an approximately constant pressure by utilizing surface of the fixed plate 105 contacting with surface of the wafer level package (BGA) 100.

In one embodiment, the print circuit board 103 is heat-resistant material, such as FR4, FR5 or BT etc. Surfaces of the fixed plate 105 and the contact springs 104 are approximately at same level, and material of the fixed plate 105 and the print circuit board 103 is the same, such as FR4, FR5 or BT etc. Moreover, the fixed plate 105 is located among the solder join socket 102. Material of the contact springs 104 is stainless steel.

The contact structure and method of burn-in and test of new type wafer level package has the advantages as follows: contact pressure is kept between the solder balls and the metal springs, each ball contact independently to a spring, longer contacting life time, not easy to damage the contact spring, easy to repair the contact micro spring, easy assembly, the lowest cost, and can be used for burn-in and test for WLP and Multi-package after packaging.

Although specific embodiments have been illustrated and described, it will be obvious to those skilled in the art that various modifications may be made without departing from what is intended to be limited solely by the appended claims.

What is claimed is:

1. A contact method of burn-in and test after packaging, comprising:
providing a print circuit board;
engaging a solder join socket with a first fixed plate, said solder join socket with contact spring located in said solder join socket;
forming an adhesive material onto a pad area of said print circuit board;
attaching said solder join socket to said adhesive material; and
engaging a second fixed plate with said first fixed plate and said solder join socket.

2. The method in claim 1, wherein said engaging a solder join socket with a first fixed plate comprises utilizing inserting said solder join socket into the hole of said first fixed plate.

3. The method in claim 1, wherein said forming an adhesive material onto pads area of said print circuit board comprises utilizing the SMT (surface mounting technology) process to print a solder paste onto said pad area of said print circuit board.

4. The method in claim 1, wherein said attaching said solder join socket to said adhesive material comprises aligning said solder join socket with said pad area.

5. The method in claim 1, further comprising performing a step of re-flowing process for electrically coupling said solder join socket with said pad after said attaching said solder join socket to said adhesive material.

6. The method in claim 5, further comprising performing a step of pushing said first fixed plate down to the top site of said print circuit board after said re-flowing process.

7. The method in claim 1, wherein said engaging a second fixed plate with said first fixed plate and said solder join socket comprises utilizing inserting said second fixed plate into said solder join socket.

8. The method in claim 1, further comprising performing a step of engaging a third fixed plate with said second fixed plate and said solder join socket after said engaging a second fixed plate with said first fixed plate and said solder join socket.

9. The method in claim 8, wherein said engaging a third fixed plate with said second fixed plate and said solder join socket comprises utilizing inserting said third fixed plate into said solder join socket following up said second fixed plate.

10. The method in claim 8, further comprising performing a step of coupling a contact ball of a package with said contact spring for performing testing after said engaging a third fixed plate with said second fixed plate and said solder join socket.

11. The method in claim 8, wherein the bore diameter of said first, second and third fixed plate are the smallest, middle and the highest respectively.
